(19) United States
(12) Patent Application Publication
(10) Pub. No.: US 2003/0117787 A1
(43) Pub. Date: Jun. 26, 2003

(54) Method and apparatus for EMI shielding

(75) Inventor: Edward Nakauchi, Westminster, CA (US)

Correspondence Address: TESTA, HURWITZ & THIBEAULT, LLP, HIGH STREET TOWER, 125 HIGH STREET, BOSTON, MA, 02110, US

(73) Assignee: LAIRD TECHNOLOGIES, INC., DELAWARE WATER GAP, PA

(21) Appl. No.: 10/273,222

(22) Filed: Oct. 17, 2002

Related U.S. Application Data
(60) Provisional application No. 60/330,044, filed on Oct. 17, 2001.

(51) Int. Cl. H05K 9/00

(52) U.S. Cl. 361/818; 361/816

(57) ABSTRACT

Electromagnetic-energy absorbing materials are used to suppress electromagnetic interference (EMI) when used in association with an electronic circuit, the absorptive material suppressing the transmission of electromagnetic interference (EMI) therefrom. Disclosed are processes and devices for fabricating absorptive materials configured for attachment to an edge of the electronic circuit. In one embodiment, an absorptive shield is prepared using an absorptive material and a fastener. In one embodiment, the fastener is an adhesive. In another embodiment, the fastener is a mechanical fastener, such as a clip and a screw. In yet other embodiments, the absorptive material is combined with a conductor to extend the frequency range of the shielding effectiveness of either the absorptive material or the conductor acting alone.

### RELATED APPLICATIONS

This application claims priority to and incorporates herein by reference in its entirety U.S. Provisional Application Serial No. 60/330,044, filed on Oct. 17, 2001, entitled Method and Apparatus for EMI Shielding.

### FIELD OF THE INVENTION

The present invention relates generally to the attenuation of electromagnetic energy and, more specifically, to attenuating electromagnetic energy associated with electronic circuitry.

### BACKGROUND OF THE INVENTION

As used herein, the term EMI should be considered to refer generally to both electromagnetic interference and radio frequency interference (“RFI”) emissions, and the term electromagnetic should be considered to refer generally to electromagnetic and radio frequency.

During normal operation, electronic equipment generates undesirable electromagnetic energy that can interfere with the operation of proximately located electronic equipment due to EMI transmission by radiation and conduction. The electromagnetic energy can be of a wide range of wavelengths and frequencies. To minimize the problems associated with EMI, sources of undesirable electromagnetic energy may be shielded and electrically grounded. Shielding is designed to prevent both ingress and egress of electromagnetic energy relative to a housing or other enclosure in which the electronic equipment is disposed. Since such enclosures often include gaps or seams between adjacent access panels and around doors, effective shielding is difficult to attain, because the gaps in the enclosure permit transference of EMI therethrough. Further, in the case of electrically conductive metal enclosures, these gaps can inhibit the beneficial Faraday Cage Effect by forming discontinuities in the conductivity of the enclosure, which compromise the efficiency of the ground conduction path through the enclosure. Moreover, by presenting an electrical conductivity level at the gaps that is significantly different from that of the enclosure generally, the gaps can act as slot antennae, resulting in the enclosure itself becoming a secondary source of EMI.

Specialized EMI gaskets have been developed for use in gaps and around doors to provide a degree of EMI shielding while permitting operation of enclosure doors and access panels. To shield EMI effectively, the gasket should be capable of absorbing or reflecting EMI as well as establishing a continuous electrically conductive path across the gap in which the gasket is disposed. Conventional metallic gaskets manufactured from copper doped with beryllium are widely employed for EMI shielding due to their high level of electrical conductivity. Due to inherent electrical resistance in the gasket, however, a portion of the electromagnetic field being shielded induces a current in the gasket, requiring that the gasket form a part of an electrically conductive path for passing the induced current flow to ground. Failure to ground the gasket adequately could result in radiation of an electromagnetic field from a side of the gasket opposite the primary EMI field.

Conventional metallic EMI gaskets, often referred to as copper beryllium finger strips, include a plurality of cantilevered or bridged fingers forming linear slits therebetween. The fingers provide spring and wiping actions when compressed. Other types of EMI gaskets include closed-cell foam sponges having metallic wire mesh knitted thereover or metallized fabric bonded thereto. Metallic wire mesh may also be knitted over silicone tubing. Strips of rolled metallic wire mesh, without foam or tubing inserts, are also employed.

One issue with conventional finger strips is that they are not as effective in EMI shielding as a clock speed of an electronic product is increased. As the clock speed is increased, the wavelength of the EMI waves produced decreases. Accordingly, the waves can penetrate smaller and smaller apertures in the enclosure and in the EMI shield. At shorter wavelengths, the slits formed in the finger shields can act as slot antennae, permitting the passage of EMI therethrough and the resultant shielding effectiveness of the shields decreases. Conventional finger strips with linear slits formed between the fingers are increasingly less effective in these applications.

Metallized fabric covered foam gaskets avoid many of the installation and performance issues of finger strips; however, they are generally not as effective in EMI shielding as finger strips. Nonetheless, EMI gaskets manufactured from metallized fabrics having foam cores are increasing in popularity, especially for use in equipment for which performance is important, but not a primary consideration.

As used herein, the term metallized fabrics include articles having one or more metal coatings disposed on woven, nonwoven, or open mesh carrier backings or substrates and equivalents thereof. See, for example, U.S. Pat. No. 4,900,618 issued to O'Connor et al., U.S. Pat. No. 4,910,072 issued to Morgan et al.; U.S. Pat. No. 5,075,037 issued to Morgan et al., U.S. Pat. No. 5,082,734 issued to Vaughn, and U.S. Pat. No. 5,393,928 issued to Cribb et al., the disclosures of which are herein incorporated by reference in their entirety. Metallized fabrics are commercially available in a variety of metal and fabric carrier backing combinations. For example, pure copper on a nylon carrier, nickel-copper alloy on a nylon carrier, and pure nickel on a polyester mesh carrier are available under the registered trademark Flectron® metallized materials from Laird Technologies, Inc., located in St. Louis, Mo. An aluminum foil on a polyester mesh carrier is available from Neptco, located in Pawtucket, R.I.

There exist, however, a number of shortcomings with application of any of the above mentioned EMI shielding methods and devices to shield EMI at the edge of an electronic circuit, such as a multi-layer printed circuit board. As a conductor, such EMI shields can be expected to impact operation of the electrical circuit to some degree. In certain applications, where the electronic circuit includes electrical power and ground layers, the direct application of a conductor could short circuit power to ground. Attempts to use a conductive EMI shield at the edge of the electronic circuit in combination with an insulator to prevent direct contact of the shield with the circuit would necessarily result in a gap. At lower frequencies (e.g., below 1 GHz), such gaps may be tolerable, but at higher frequencies, the EMI penetrating the gap can be substantial and unacceptable.

Furthermore, for higher-frequency electronic circuits, placing a conductive shield at the edge of the circuit may also perturb the electromagnetic field distribution within the circuit. For example, a conducting EMI shield can result in unwanted internal reflections, capable of adversely impacting the operation of transmission lines contained therein. Such adverse impacts might possibly be avoided during the design phase through available compensation techniques. Unfortunately, however, such design compensation techniques would generally be unavailable for the application of a conductive shield to an already designed circuit, a practice common in the field of mitigating EMI.

Accordingly, there is a need in the art for EMI shields that exhibit substantial shielding effectiveness at frequencies above 1 GHz, and avoid the shortcomings of conventional EMI shields. Additionally, there is a need in the art for alternative EMI shields that are adaptable for treating EMI at an edge of an electronic circuit.

### SUMMARY OF INVENTION

In general, the present invention relates to a shield for preventing EMI along an edge of an electronic circuit by providing an RF absorbing material in electrical communication with the edge of the circuit to intercept electromagnetic fields and remove a portion of the energy contained within the intercepted fields, thereby reducing the EMI. The EMI-absorbing material absorbs a portion of the EMI incident upon the shield, thereby reducing transmission of EMI therethrough over a range of operational frequencies. The absorbing material may remove a portion of the EMI from the environment through energy conversion resulting from loss mechanisms. These loss mechanisms include polarization losses (i.e., permittivity and permeability) in a dielectric material and conductive, or ohmic, losses in a conductive material having a finite conductivity.

Accordingly, in a first aspect, the invention relates to a shield for reducing radio frequency (RF) interference associated with an electronic circuit, in which the shield includes an RF absorber configured to be in electrical communication with an edge of the electronic circuit. The RF absorber reduces associated RF interference relating to electromagnetic fields present at the edge of the electronic circuit by intercepting the fields and removing a portion of the energy contained therein through energy conversion.

In one embodiment, the RF absorber is combined with a fastener configured to maintain the absorber in a substantially fixed relationship with respect to the edge of the electronic circuit. The fastener may be a chemical fastener, such as an adhesive, or a mechanical fastener, such as a clip. In some embodiments, the fastener is non-conducting, such as a dielectric; whereas, in other embodiments, the fastener is conducting, such as a metal. In one embodiment, the mechanical fastener is fixedly attached to the electronic circuit, such as with an adhesive, or solder. In other embodiments, the mechanical fastener is removably attached to the electronic circuit, such as with one or more screws, or with a compression fitting.

In one embodiment the RF absorber is configured along an interior surface of a clip. In another embodiment, the RF absorber is configured along an exterior surface of a clip. In yet another embodiment, the RF absorber is configured along both the interior and the exterior of a clip, with respect to an edge of the electronic circuit.

In another embodiment, an RF absorber is applied as a first layer to a substrate. In some embodiments, the substrate is flexible, such as a tape. The tape-absorber combination may also include an adhesive for securing the combination to an edge of the electronic circuit.

In some embodiments, the RF absorber includes an absorbing material selected from the group of consisting of alumina, sapphire, silica, titanium dioxide, steel wool, carbon-impregnated rubber, ferrite, iron, iron silicide, graphite, carbon, carbon in a plastic stranded carrier, paste composites, and combinations thereof. In other embodiments, the RF absorber is a composite including an absorbing material bound within a matrix material. The matrix material can include a polymer selected from the group of consisting of silicone, fluorosilicone, isoprene, nitrile, polyethylene, chlorosulfonated polyethylene, neoprene, fluoroelastomer, urethane, thermoplastic, thermoplastic elastomer (TPE), polyamide TPE, thermoplastic polyurethane (TPU), and combinations thereof. The matrix material can also include epoxy.

In another aspect, the invention relates to a method for reducing radio frequency (RF) interference associated with an electronic circuit including the steps of providing an RF absorber and positioning the RF absorber to be in electrical communication with a first edge of an electronic circuit, such that the positioned absorber intercepts electromagnetic fields. The positioned absorber then reduces the associated RF interference by removing a portion of the energy contained within the intercepted fields through energy conversion.

In one embodiment, the method includes the additional step of fastening the RF absorber to the first edge of the electronic circuit. The absorber may be fastened using an adhesive and/or using a mechanical fastener. In another embodiment, the method includes the step of directly depositing the absorber onto the first edge of the electronic circuit. Methods of directly depositing the absorber include form-in-place, painting, inking, dipping, spraying, sputtering, and chemical vapor deposition.

The RF absorber may be applied to the edge of the electronic circuit by selectively depositing several RF absorbing components, each spaced from an adjacent component. In some embodiments, the absorber is deposited on the first edge of the electronic circuit, such that a thickness of the deposited RF absorber along the first edge is non-uniform with respect to the first edge. In yet another embodiment, the RF absorber is deposited as a first layer including a first absorbing material and a second layer including a second absorbing material.

In yet another aspect, the invention relates to a shield for reducing radio frequency (RF) interference associated with an electronic circuit, the shield including suitable means for absorbing RF energy. The RF absorbing means is configured to be in electrical communication with an edge of the electronic circuit, such that the absorbing means intercepts electromagnetic fields and removes a portion of the energy contained therein through energy conversion, thereby reducing associated RF interference. In one embodiment, the shield further includes means for securing the RF absorbing means to the electronic circuit.

### BRIEF DESCRIPTION OF THE DRAWINGS

The invention is pointed out with particularity in the appended claims. The advantages of the invention may be better understood by referring to the following description, taken in conjunction with the accompanying drawings, in which:

FIGS. 1A through 1C are schematic diagrams depicting perspective views of alternative embodiments of an RF absorber in electrical communication with an edge of an electronic circuit;

FIGS. 2A and 2B are schematic diagrams depicting perspective views of alternative embodiments of the RF absorber of FIGS. 1A through 1C configured for attachment to an edge of the electronic circuit;

FIG. 3 is a schematic diagram depicting a perspective view of one embodiment of the RF absorber illustrated in FIGS. 1A through 1C and FIGS. 2A and 2B, in which the absorber is configured as a composition;

FIG. 4 is a schematic diagram depicting a perspective view of an exemplary alternative embodiment of an RF absorber including an adhesive for attaching the absorber to an edge of the electronic circuit;

FIGS. 5A and 5B are schematic diagrams depicting perspective views of exemplary alternative embodiments of an RF absorber including a first adhesive layer for attaching the absorber to a chassis, and first and second adhesive layers for attaching the absorber to the chassis and to an edge of the electronic circuit, respectively;

FIGS. 6A and 6B are schematic diagrams depicting perspective views of exemplary alternative embodiments of an RF absorber including a clip for attaching the absorber to an edge of the electronic circuit intimately, and with a gap, respectively;

FIGS. 7A through 7C are a schematic diagrams depicting perspective views of exemplary alternative embodiments of the RF absorber clip attachment combinations illustrated in FIGS. 6A and 6B;

FIG. 8 is a schematic diagram depicting a perspective view of an exemplary alternative embodiment of the RF absorber-clip combinations illustrated in FIGS. 6A and 6B for securing an absorber to an edge of the electronic circuit, where the absorber has a height greater than the height of the electronic circuit;

FIGS. 9A and 9B are schematic diagrams depicting perspective views of exemplary alternative embodiments of the RF absorber-clip combination illustrated in FIGS. 6A and 6B, in which the absorber is located on the exterior surface of the clip with respect to the proximate electronic circuit edge;

FIG. 10 is a schematic diagram depicting a perspective view of an exemplary alternative embodiment of the RF absorber clip illustrated in FIGS. 6A and 6B, in which the absorber is located on both the interior and the exterior surfaces of the clip, with respect to the proximate electronic circuit edge;

FIG. 11 is a schematic diagram depicting a perspective view of an exemplary alternative embodiment of an RF absorber layered upon a flexible tape substrate and attached to an edge of the electronic circuit;

FIG. 12A is a schematic diagram depicting an exemplary alternative embodiment in which multiple RF absorbing components are configured along an edge of the electronic circuit;

FIG. 12B is a schematic diagram depicting an exemplary alternative embodiment of the RF absorber in FIGS. 1 through 12A, in which the thickness of the absorber varies with respect to the edge of the electronic circuit; and

FIGS. 13A and 13B are schematic diagrams depicting exemplary embodiments of the RF absorber of FIGS. 1 through 12B applied along several edges of the electronic circuit and along an entire perimeter of the electronic circuit, respectively.

### DETAILED DESCRIPTION OF THE INVENTION

An electromagnetic shield can include materials having electromagnetic-energy absorbing properties that can be used to suppress the transmission of EMI over a broad range of frequencies. Such EMI-absorbing materials can provide substantial electromagnetic shielding effectiveness, for example, up to about 3 dB or more at EMI frequencies occurring up to about 100,000 megahertz. Generally, the terms shield and shielding and their derivatives, as used herein, include any devices and/or method designed to reduce EMI. For example, a shield can operate to eliminate or minimize electromagnetic fields through a combination of one or more of a variety of techniques including reflection, diffraction, conduction, and absorption.

One area in which EMI-absorbing materials can be used as shielding is electronic circuits. Typical embodiments of electronic circuits include multi-layer electronic circuits having one or more layers of electrical conductor in combination with one or more layers of dielectric. The electrically conducting layers can be formed as a plane extending over substantially the entire surface area of the electronic circuit, or, alternatively, over one or more sub-regions of the surface area. Additionally, one or more of the conducting layers can further include conductive traces forming a predetermined pattern for routing electrical signals, accommodating the attachment of electrical components, shielding, and the like.

Notably, electronic circuits can be formed as rigid devices, or alternatively, as flexible devices. Some examples of rigid electronic circuits include circuit boards (e.g., printed circuit boards). Other examples of rigid electronic circuits include rigid substrates, such as ceramic circuit substrates commonly used in electronic subassemblies and components. Yet other examples of rigid electronic circuits include “etched” microelectronic devices, such as those formed using crystalline-type substrates including, for example, silicon and gallium-arsenide (GaAs). Some examples of flexible electronic circuits include circuits formed upon a flexible substrate, such as polyesters (e.g., Mylar®), and are commonly referred to as flexprint circuits. Other examples of flexible circuits include circuits formed with fabric-based substrates.

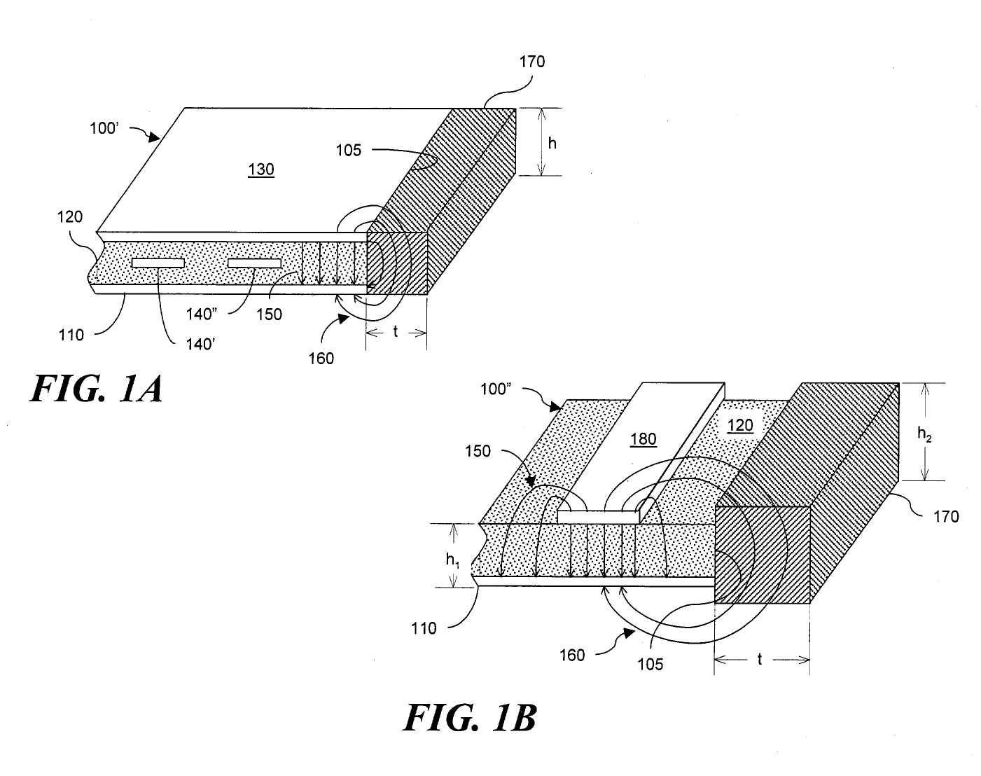

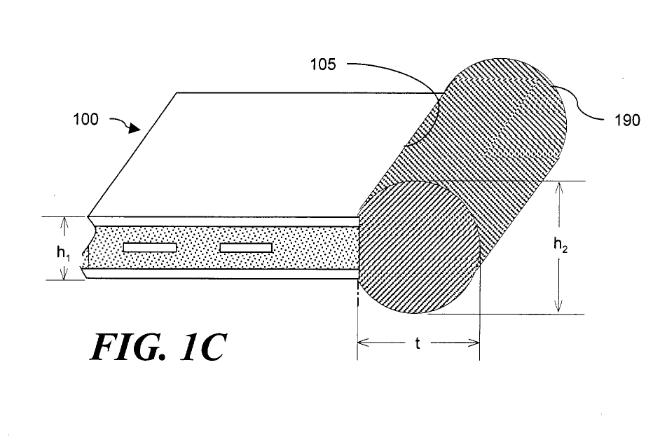

According to the present invention, in one embodiment, EMI-absorbing materials can be formed in a solution capable of being applied to a substrate. FIGS. 1A and 1C illustrate perspective views of alternative embodiments of an EMI shield that includes a radio frequency (RF) absorber in electrical communication with an edge of exemplary electronic circuits. In reference to FIG. 1A, electronic circuits, such as the partial cut-away schematic diagram of a multi-layer electronic circuit 100′, define a circuit edge 105. The circuit 100′ further includes a first conducting layer 110, a dielectric layer 120, and a second conducting layer 130. The dielectric layer 120 may, for example, be disposed between the first and second conducting layers 110, 130. One or more additional conducting and/or dielectric layers may also be disposed between the first and second conducting layers 110, 130. For example, traces 140′ and 140″, generally 140, represent electrical conductors disposed within the dielectric 120. These traces 140 may carry electrical signals, power, or even ground.

The conducting layers 110, 130, 140 are generally fabricated from good electrical conductors, such as copper, aluminum, gold, silver, nickel, tin, lead, alloys, and combinations thereof. The one or more dielectric layers 120 are generally fabricated from flexible insulators, such as Mylar®, and/or rigid insulators, such as epoxy-based resins, thermoset fiberglass epoxy laminates (e.g., FR4, G10), Duriod®, Polymide, and Teflon®.

In one particular embodiment, the first conducting layer 110 represents a ground plane, generally in electrical communication with a ground reference potential. In contrast, the second conducting layer 130 may represent a power plane, generally in electrical communication with a positive or negative electrical potential, as measured with respect to the ground plane 110. In some embodiments, the plane 130 may alternatively represent a second ground plane, with signals being distributed along on one or more traces 140.

Disposed between the first conducting layer 130 (e.g., power plane) and the second conducting layer 110 (e.g., ground plane) is an electrically insulating dielectric layer 120. In some embodiments, the insulating dielectric layer 120 may serve as a rigid support for the conducting layers 110, 130, such as is commonly know with respect to printed circuit boards. Alternatively, in other embodiments, the dielectric layer 120 may serve as a flexible support for the conducting layers 110, 130, such as is commonly known with respect to flexible circuit assemblies, such as flexprint and fabric-based circuits. In either embodiment, the dielectric layer 120 may include a plurality of dielectric layers interstitially disposed between additional dielectric, and/or conducting layers (e.g., signal layers, such as the signal traces 140 shown). Generally, the dielectric layer 120 serves as an insulator preventing unintentional contact between and among the conducting layers 110, 130, and traces 140.

Electronic circuit embodiments including one or more traces 140 between a conducting plane 130 and ground plane 110, such as the one illustrated in FIG. 1A, represent one technique to prevent EMI. Electrical currents residing on the conducting layers 110, 130, and traces 140 give rise to electromagnetic fields, as illustrated by the exemplary electromagnetic field lines 150, 160. Generally, electromagnetic field lines relating to electrical currents along interior portions of the electronic circuit 100′ will be contained therein, as shown by the interior field lines 150. However, electromagnetic field lines at or near the circuit edge 105 will give rise to fringing fields 160. The fringing fields, generally extend beyond the internal regions of the electronic circuit 100′ and can give rise to radiating electromagnetic fields. Such radiating electromagnetic fields can lead to EMI with any other collocated or external systems and devices.

An absorptive shield 170 of a thickness, t, greater than a predetermined minimum thickness, tₘᵢₙ, is placed in electrical communication alongside the circuit edge 105 to intercept a portion of the electromagnetic field 160 emanating therefrom. Generally, for optimal performance, tₘᵢₙ should be selected to be at least equal to the skin depth, as discussed more fully hereinbelow. The physical properties of the absorptive shield 170 are such that the absorptive shield 170 converts a portion of the energy contained within the intercepted electromagnetic field into heat through one or more loss mechanisms. For example, an RF absorber having a relative permeability “μᵣ,” value greater than 1, will result in a loss from currents induced in the absorber, in a manner similar to the loss caused by the electrical current flowing through a resistor (i.e., “I²R” loss). As the physical properties of the absorptive shield 170 generally vary with the frequency of the time varying electromagnetic fields, the absorptive shield 170 is selected to exhibit desirable physical properties (e.g., permeability) over the intended frequency range (i.e., above about 1 GHz).

The amount of energy absorbed depends in part on the portion of the electromagnetic field intercepted by the absorptive shield 170. The extent of the intercepted electromagnetic field is controllable by the overall dimensions of the absorptive shield 170. For example, the extent of the intercepted electromagnetic field is controllable through variations in the length, or longitudinal extent of the absorptive shield 170, as measured along the circuit edge 105. Similarly, the extent of the intercepted electromagnetic field is controllable through variations in the shape and/or size of the cross-sectional area of the absorptive shield 170. The size of the cross-sectional area can be varied through one, or both of the thickness, t, and the height, h, of the absorptive shield 170, as measured in a plane perpendicular to the circuit edge 105.

The selectable thickness of the absorptive shield 170 also controls the overall loss effectiveness of the absorptive shield 170 by controlling the amount of electrical current contained therein over the desired operational frequency range. Generally, as the frequency of electrical currents flowing through a conductor increases, the current densities associated therewith tend to concentrate toward the surface of the conductor. One term used by those skilled in the art is the skin depth, “δ,” which is generally related to the depth at which the amplitude of an electromagnetic wave penetrating a material is attenuated by a value of approximately 87%. As the penetrating electromagnetic fields induce currents within the material, the skin depth defines a cross-sectional area within which a predetermined amount of total induced current density is contained. Accordingly, an absorptive shield 170 designed with a thickness, t, of 1×δ would contain approximately 87% of the current induced by the intercepted electromagnetic fields. An absorptive shield 170 designed with a thickness greater than one skin depth (i.e., d≧δ) would therefore contain greater than 87% of the current induced by the intercepted electromagnetic fields resulting in a greater I²R loss.

The skin depth is generally a function of frequency, relating to the frequency of the induced current. For a good conductor, the skin depth may be estimated as

δ=(πμfσ)^{-0.5} (1)

where “f” is the frequency in hertz, “μ” is the magnetic permeability of the material, and “σ” is the conductivity of the material.

Illustrated in FIG. 1B is an alternative embodiment of an absorptive shield 170 configured to absorb electromagnetic energy present at the circuit edge 105. An alternative electronic circuit 100″ is illustrated that also includes a ground plane 110 disposed upon a first side of a dielectric layer 120; however, the circuit 100″ does not include a second electrically conducting plane 130 disposed upon a second side of the dielectric layer 120 opposite from the ground plane 110. A trace 180 carrying electrical currents may be disposed upon the dielectric layer 120, opposed to the ground plane 110. Depending upon the frequencies of electrical currents residing on the trace 180, and the extent of the ground plane 110 with respect to the trace, a majority of the electromagnetic fields can be contained within the electronic circuit 100″. The electromagnetic field lines 150 drawn between the trace 180 and the interior portion of the ground plane represent electromagnetic fields generally contained within the electronic circuit 100″. As noted in the electronic circuit 100′ with respect to FIG. 1A, electromagnetic fields may depart from the bounds of the electronic circuit 100′ and 100″, such as the fields 160 drawn between the trace 180 and the exterior portion of the ground plane. Electromagnetic fields 160 extend more prominently from the electronic circuit 100″ when the trace 180 is located near the circuit edge 105. As described above in reference to FIG. 1A, an absorptive shield 170 having a predetermined thickness, t, and located along the circuit edge 105 can intercept a portion of the electromagnetic fields 160, converting the energy contained therein to an alternate energy form, such as heat, thereby removing the RF interference associated therewith.

The height, h₂, of the absorptive shield 170 is selectable and is measured in a dimension parallel to the height, h₁, of the electronic circuit 100′, 100″, generally 100. For example, the height h₂ can be selected to be substantially the same as h₁, thereby maintaining the profile of the electronic circuit 100. Alternatively, the height h₂ can be selected to be greater than the height h₁ of the electronic circuit 100, thereby increasing the amount of intercepted electromagnetic fields. In an alternative embodiment, illustrated in FIG. 1C, a generalized absorptive shield 190 can have an arbitrary cross-sectional shape, defined in a plane containing a cross-section of the electronic circuit. A generally circular-shaped absorptive shield 190 is illustrated. Such a shield 190 can be made by casting, molding, machining, extruding, or other suitable process. Also, although the absorptive shield 190 is illustrated as having a uniform shape along the circuit edge 105, the cross-sectional shape of the absorptive shield 190 may vary along the length of the circuit edge 105. For example, the cross-sectional shape may be enlarged towards the center of the length of the circuit edge 105. Alternatively, the dimensions of the shield's cross-section may be tapered in from the ends toward the center of the length of the circuit edge 105. Alternatively or additionally, dimensions of the shield's cross-section can vary in form along the length of the edge 105, for example, transitioning from circular profile to semicircular profile, or even rectangular profile, to accommodate interfacing cables, connectors, etc.

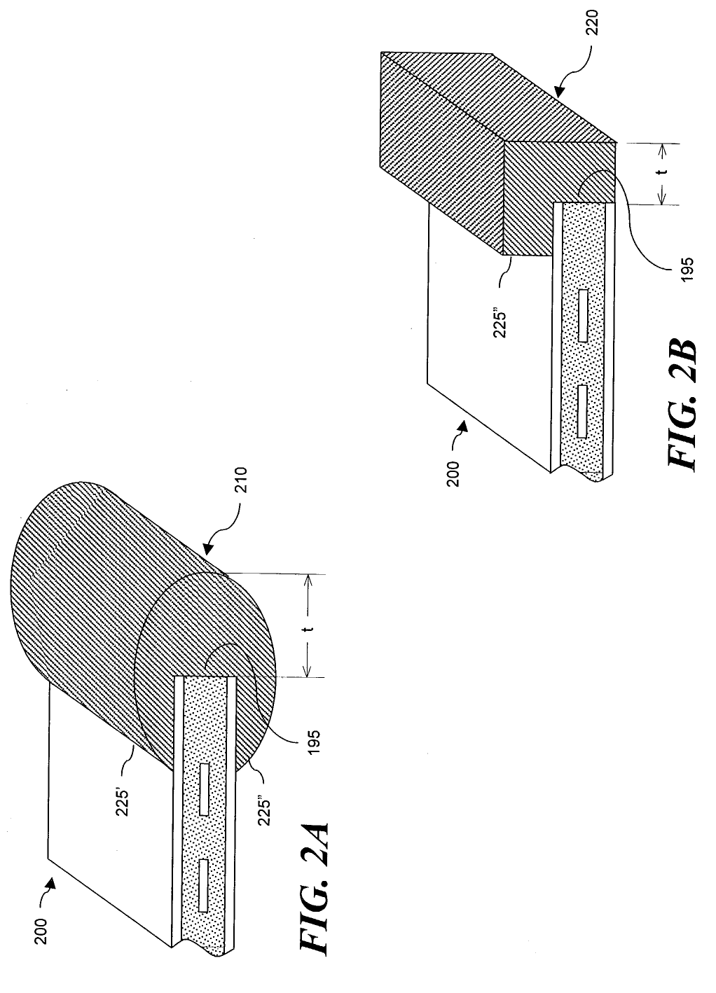

FIGS. 2A and 2B illustrate schematic diagrams depicting perspective views of alternative embodiments of absorptive shields positioned along an edge 195 of an electronic circuit 200. Whereas the absorptive shields 170 illustrated in FIGS. 1A through 1C are positioned to extend along and away from the circuit edge 105 in a non-overlapping manner, the alternate absorptive shields 210, 220 can be configured to be in electrical communication with the electronic circuit 200, while extending over at least a portion of the circuit 200 along the circuit edge 195.

For example, the embodiment shown in FIG. 2A, an absorbing shield 210 of an arbitrary cross-section can be configured with at least two overlapping portions 225′, 225″, generally 225, extending over both the top and bottom surfaces of the electronic circuit 200. Alternatively, in another embodiment shown in FIG. 2B, an absorbing shield 220 can be configured with at least one overlapping portion 225″ extending over either the top or the bottom surface of the electronic circuit 200, but not both surfaces. For example, the absorptive shield 220 can be prepared as an “L” channel, such that one leg of the L 225 overlaps either the top or the bottom of the electronic circuit 200. The overlapping portion 225 may be used to secure the absorptive shield 220 to the electronic circuit. The absorbing shield 210 of FIG. 2A has been prepared as a “U” channel, such that the two parallel legs of the channel 225 overlap both the top and bottom of the electronic circuit 200. In other embodiments, the overlaps 225′ and 225″ can overlap the electronic circuit 200 by different amounts.

As shown in FIGS. 2A and 2B, the absorptive shield 210, 220 can be applied directly to the electronic circuit 200. In one embodiment, the absorptive shield 210 can be configured from an absorbing solution selectively applied to the circuit edge 195 and cured thereon. For example, the absorbing solution can be applied as paint by brushing, dipping, or spraying. The absorbing solution can also be applied as ink, for example, selectively applying the absorptive ink using a mask or screen. Alternatively, the directly applied absorptive shield 210, 220 can be configured from either an absorbing solid or absorbing solution through the process of sputtering (e.g., RF sputtering). Similarly, the absorbing solid or absorbing solution can be applied to the electronic circuit 200 using chemical vapor deposition. The shield 210 can also be formed in place as a viscous deposit. Any of the above-described methods of application may be repeated and/or combined to deposit an absorptive layer having a predetermined thickness, t. Pending U.S. patent application Ser. No. 09/768,428, entitled “Method and Apparatus for EMI Shielding” and filed on Oct. 17, 2001, describes methods for applying material to a substrate, the specification of which is herein incorporated by reference in its entirety.

In general, the absorptive shield is constructed using one or more materials that absorb RF over the desired frequency range (e.g., above 1 GHz). For example, the absorptive shield can be constructed from an absorbing material. Some examples of EMI-absorbing materials include carbon, carbon fibers, alumina (Al₂O₃), sapphire, silica (SiO₂), titanium dioxide (TiO₂), ferrite, iron, iron silicide, graphite, and composites with different combinations of iron, nickel, and copper. The aforementioned EMI-absorbing materials are generally solids over anticipated ambient operating temperatures and pressures. Accordingly, the desired shape of the absorptive shield can be achieved, for example, by molding, casting, and/or machining.

Various U.S. patents describe absorbing, or lossy, materials and their uses. See, for example, U.S. Pat. No. 4,408,255 issued to Adkins, U.S. Pat. No. 5,689,275 issued to Moore et al., U.S. Pat. No. 5,617,095 issued to Kim et al., and U.S. Pat. No. 5,428,506 issued to Brown et al., the disclosures of which are herein incorporated by reference in their entirety. Some manufactures of lossy materials are R&F Products of San Marcos, Calif.; ARC Technical Resources, Inc., of San Jose, Calif.; Tokin America, Inc., of Union City, Calif.; Intermark-USA, Inc., of Island City, N.Y.; TDK of Mount Prospect, Ill.; and Capcon of Inwood, N.Y.

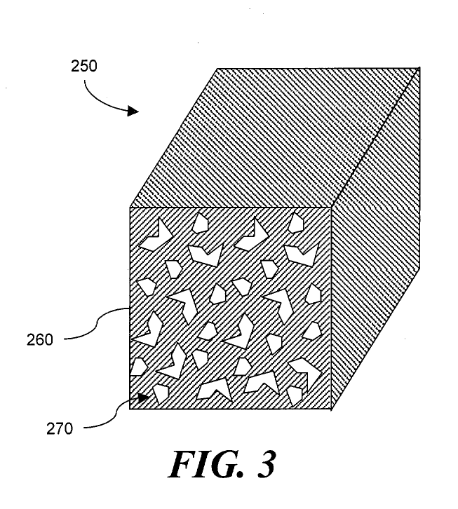

Alternatively, the absorptive shield can be constructed as a composite. FIG. 3 illustrates one such embodiment of a composite absorptive shield 250, in which a matrix 260 is formed from a binding agent maintaining a number of RF absorbing particles 270 in suspension. The absorbing particles 270 can be any of the above-mentioned RF absorbers individually or in combination.

The binding agent may be selected to formulate the composite 250 as a freestanding absorptive shield. Alternatively, the binding agent may be selected to bind the absorbing particles 270 and adhere them to the electronic circuit. In some embodiments, a binding agent is selected that cures with a compliant and resilient consistency. In one embodiment, for example, the binding agent is an elastomer, a foam, or any suitable polymer resin binder. The binding agent may be a rubber, such as a natural latex rubber, a synthetic rubber, such as styrene butadiene rubber (SBR), silicone, ethylene propylene diene monomer (EPDM), or a proprietary binder. Binders having a resilient consistency adhere the EMI-absorbing material to a flexible or supple substrate, while allowing the substrate to remain flexible or supple. In other embodiments, however, a binding agent is selected that cures with a less resilient or even rigid consistency. One example of a rigidly-curing binding agent is an epoxy resin.

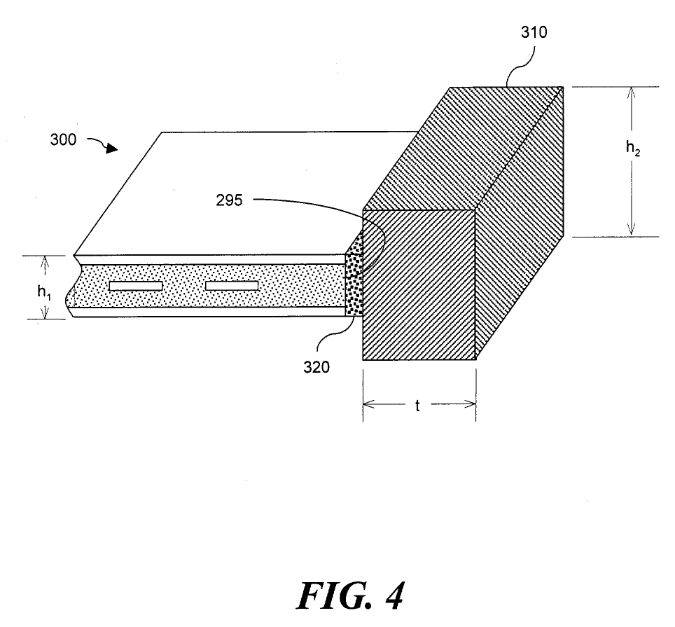

FIG. 4 illustrates an alternative embodiment of an EMI shield including an RF absorber, which further includes an adhesive for attaching the absorber to an edge of an electronic circuit. A cross-sectional, partial cut away view of a generalized electronic circuit 300 defining an edge 295 is secured to an absorptive shield 310 using an interstitial chemical adhesive 320. The adhesive 320 can be a hard curing adhesive, such as an epoxy resin, UV-cure adhesives, or thermal setting glue. Alternatively, the adhesive 320 can be a pressure sensitive adhesive (PSA) and, therefore, removable and re-locatable. PSAs include any of the available adhesive compounds, for example, used in the manufacture of adhesive tapes. In general, the adhesives can include electrically conductive adhesives as well as non-electrically conductive adhesives.

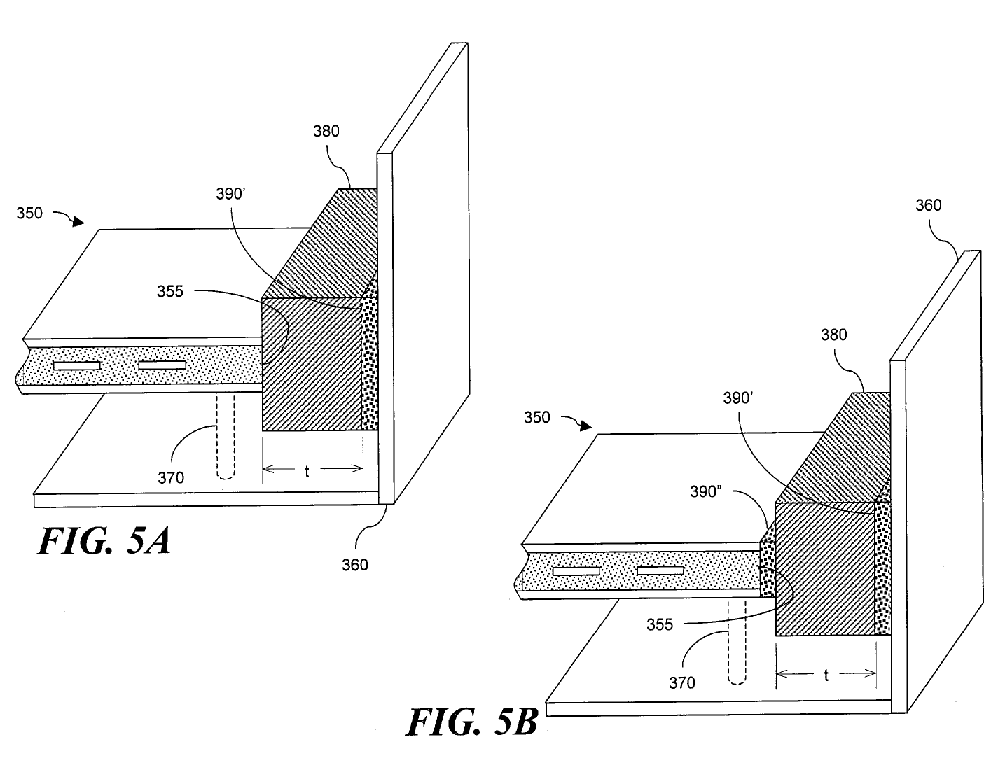

FIGS. 5A and 5B illustrate alternative embodiments of an absorbing shield positioned along an edge of an electronic circuit using chemical adhesives, in which the shield is fastened to a structure other than the electronic circuit. Referring to FIG. 5A, a generalized electronic circuit 350 defining an edge 355 is secured in relation to an external structure, such as a chassis 360, such that the position of the electronic circuit 350 relative to the chassis 360 is substantially fixed. The positional relationship of the electronic circuit 350 may be fixed with respect to the chassis 360, for example, using one or more mounting standoffs 370. An absorptive shield 380 can be placed between the electronic circuit 350 and the chassis 360. The absorptive shield 380 can be securely attached to the chassis 360 using a first adhesive layer 390′. As the position of the electronic circuit 350 is fixed with respect to the chassis 360, the absorptive shield 380 is maintained substantially along the circuit edge 355. For further support, as illustrated in FIG. 5B, a second adhesive layer 390″ can be applied to an opposing surface of the absorptive shield 380 adjacent to the electronic circuit 350 such that the shield 380 is securely fastened to both the chassis 360 and the circuit edge 355.

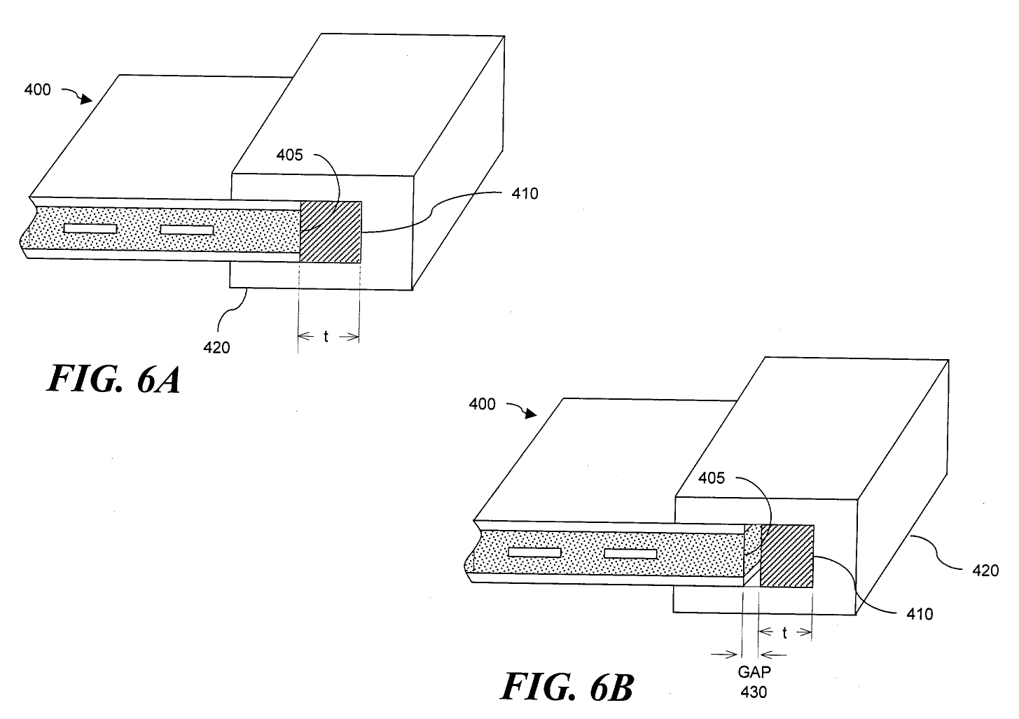

Referring now to FIGS. 6A and 6B, alternative embodiments of an absorptive shield including an RF absorber and a mechanical fastener are illustrated. Again, a cross-sectional perspective view of a generalized electronic circuit 400 defining an edge 405 is illustrated in partial cutaway. An absorptive material 410 having a predetermined thickness, t, is positioned along circuit edge 405. The absorptive material 410 is attached to the circuit edge 405 through a mechanical fastener 420. For example, as illustrated in FIG. 6A, the mechanical fastener 420 can be a “U” channel, in which the interior dimension of the parallel surfaces is sized to accept the predetermined absorber thickness t. The absorptive material 410 can then be placed in the “bottom,” or trough, of the U channel 420 and the U channel 420 fastened to the electronic circuit 400 using the portions of the parallel surfaces extending beyond the absorptive material 410 contained therein.

It is not necessary for the absorptive material 410 to make intimate contact with the circuit edge 405. Accordingly, as illustrated in FIG. 6B, the absorptive material 410 can be positioned to maintain a gap 430 between a surface of the absorptive material 410 and the circuit edge 405, while still maintaining the absorptive material 410 in electrical communication with the circuit edge 405. The gap 430 can be intentional or unintentional and may extend over all or merely a portion of the circuit edge 405. In some embodiments, the gap 430 may be desired for cooling. The overall shielding performance of the absorptive shield may generally be greatest for configurations where the absorptive material 410 is placed as close as possible to the circuit edge 405, as the magnitudes of the electromagnetic fields are generally the greatest at the circuit edge 405.

Generally, the mechanical fastener 410 can be constructed of either a dielectric material, or of a conducting material, or of any combination of both dielectric and conducting materials. Dielectric embodiments may be used, particularly where electrical contact between the top and bottom portions of the electronic circuit 400 would be disadvantageous (e.g., avoiding a short circuit between power and ground planes). Alternatively, conductive embodiments may be used, particularly where low frequency shielding (e.g., frequencies below about 1 GHz) of the circuit edge 405 is desired.

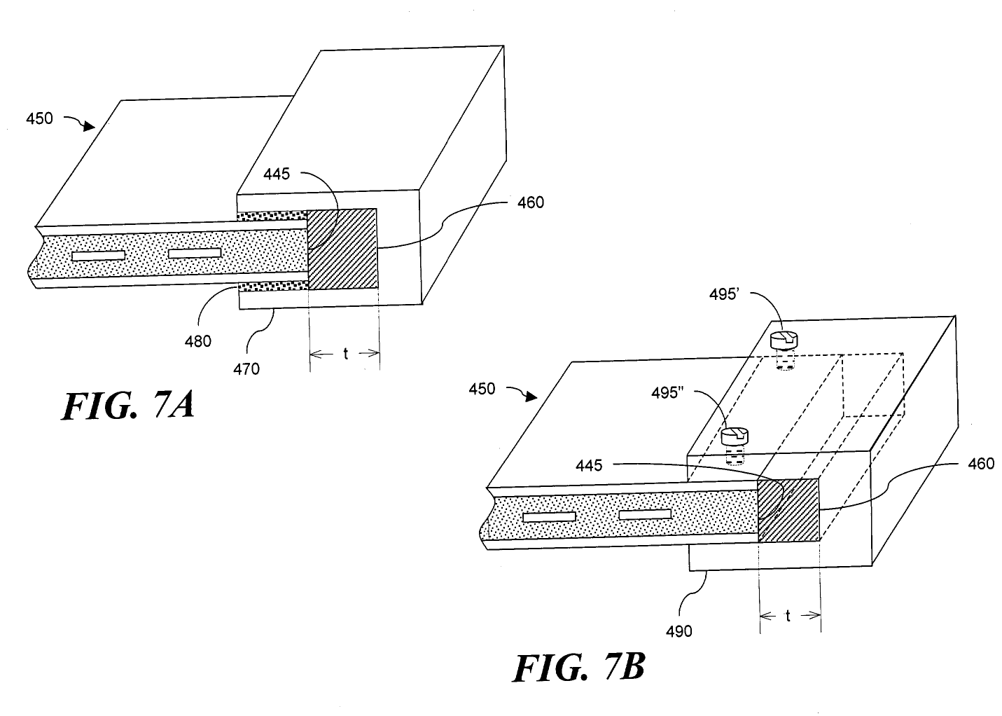

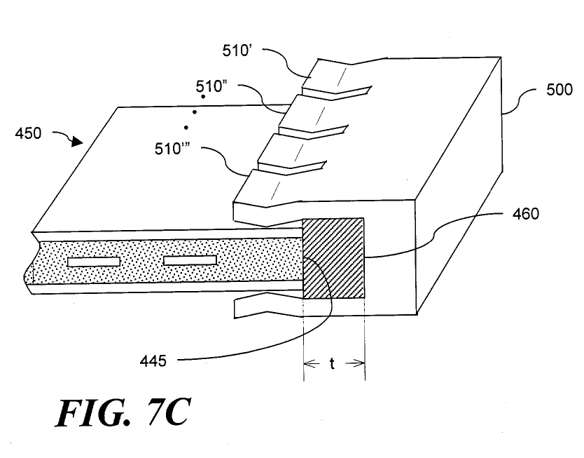

FIGS. 7A through 7C illustrate exemplary alternative embodiments of mechanical fasteners for securing the shield to an edge 445 of a generalized electronic circuit 450. Referring to FIG. 7A, an absorptive material 460 of a predetermined thickness t, is fastened to a circuit edge 445 using a mechanical fastener 470. The mechanical fastener 470 may be a U channel as illustrated, although other embodiments are anticipated, such as an L bracket. At least a portion of the mechanical fastener 470 overlaps a portion of the top surface, or the bottom surface, or the top and bottom surfaces of the electronic circuit 450. The overlapping portion of the mechanical fastener 470 is then fastened to the circuit edge 445 using a fastening compound 480. The fastening compound 480 may be an adhesive compound for fastening the mechanical fastener 470 and the absorptive material 460 to the circuit edge 445, as previously described. The fastening can be implemented in a removable fashion, for example using a pressure-sensitive adhesive as the fastening compound 480. Alternatively, the fastening can be implemented in a fixed or permanent fashion, for example using an epoxy. For embodiments in which the mechanical fastener is electrically conducting, the compound 480 can be a solder.

In another embodiment, as illustrated in FIG. 7B, an absorptive shield includes a mechanical fastener 490 and an absorptive material 460 and is attachable to the electronic circuit 450 using the mechanical fastener 490. The mechanical fasteners 490 can also secure the absorptive material 460 to the electronic circuit 450 in a removable fashion, for example using screws 495′, 495″, generally 495, or in a fixed fashion using a rivet, or similar non-removable mechanical fastener. Alternatively, referring now to another embodiment shown in FIG. 7C, the absorptive material 460 can be secured to the circuit edge 445 using a shield that includes a mechanical fastener 500 and a compression fitting. The surface of the compression fitting generally applies a force directed toward the mating and opposing surface of the electronic circuit 450. The compression fitting can include one or more “fingers” 510′, 510″, 510′″, generally 510, designed to removably fasten the mechanical fastener 500 to the circuit edge 445. The particular fingers 510 illustrated are merely exemplary, and any combination of compression fittings are anticipated (e.g., fingers residing on one side of the electronic circuit 450 only, a single finger extending over the entire length of the fastener 500, and multiple fingers extending either perpendicular or parallel to the circuit edge 445).

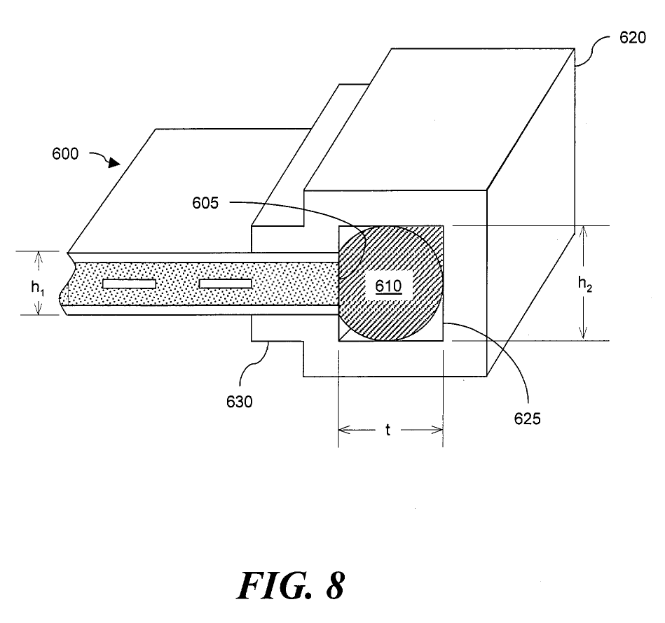

FIG. 8 illustrates an alternative embodiment of the previously described absorptive material-mechanical fastener shield combinations designed to accommodate arbitrarily-shaped absorptive materials. In general, an electronic circuit 600 defining an edge 605 and having a height of hi is illustrated with an arbitrarily shaped absorptive material 610 of a predetermined thickness, t, and a height, h₂, that may be greater or less than the height of the electrical circuit 600, h₁. The absorptive material 610 is fastened to circuit edge 605 using a mechanical fastener 620 defining a cavity 625 for containing the absorptive material 610. The mechanical fastener 620 also includes a bracket 630 for securing the fastener 620 to the electronic circuit 600. The bracket 630 may be fastened to the electronic circuit using any of the previously disclosed methods and devices.

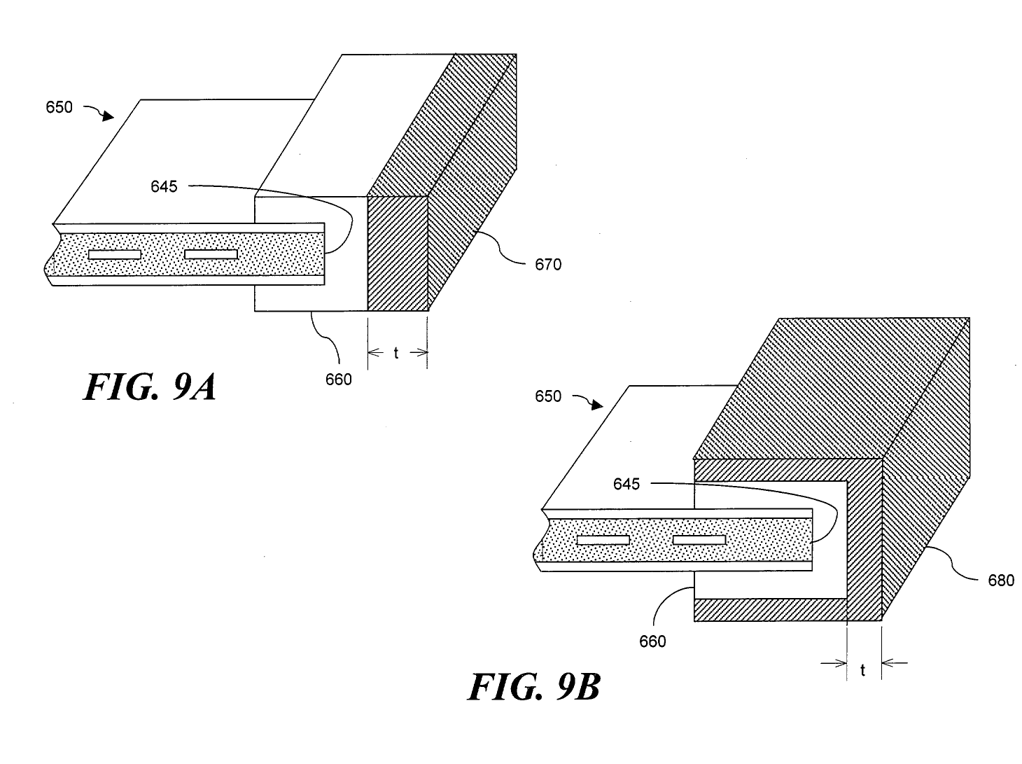

FIGS. 9A and 9B disclose alternative embodiments of a shield including a mechanical fastener in which the absorptive material is affixed to the external surface of the fastener. Referring to FIG. 9A, an interior surface of a fastener 660 is attached to an edge 645 of a generalized electronic circuit 650. The fastener, in turn, includes an absorptive material 670 attached to at least one of the exterior surfaces at a predetermined thickness, t, with respect to the circuit edge 645. FIG. 9B illustrates an embodiment in which an absorptive material 680 is attached to multiple exterior surfaces of the mechanical fastener 660. The absorptive material 680 can be fastened to the fastener 660 using any of the previously disclosed methods and devices.

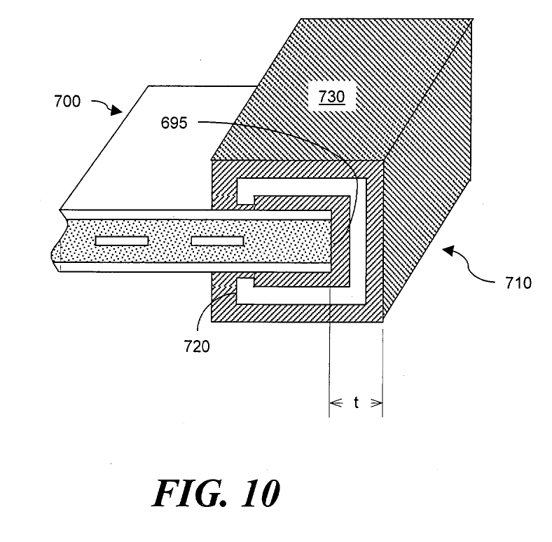

FIG. 10 illustrates an embodiment of an absorptive shield in which an absorptive shield 710 including a mechanical fastener 720 coated on substantially all sides with an absorptive material 730 is attached to an edge 695 of a generalized electronic circuit 700. The mechanical fastener can be constructed from a dielectric material, a conducting material, or a combination of dielectric and conducting materials. The shield 710 may be fastened to the electronic circuit 700 using any of the previously disclosed methods and devices.

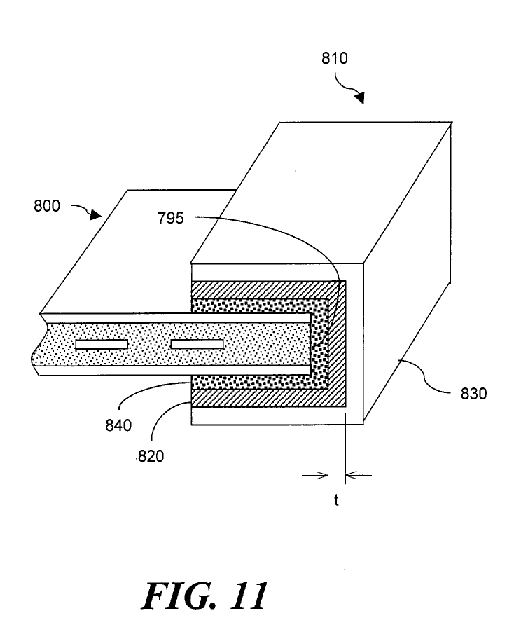

Illustrated in FIG. 11 is an alternative embodiment of an absorptive shield 810 in which the absorptive shield 810 includes an absorptive material 820 layered to a predetermined thickness, t, upon a flexible substrate 830. The absorptive shield 810 can be attached, for example to an edge 795 of a generalized electronic circuit 800. The flexible substrate 830 can be formed as a tape, being fabricated from a dielectric material, such as plastic, a conductive material, such as copper, or a combination of dielectric material and conductive material, such as a copper tape coated on one side with a dielectric (i.e., corrosion inhibiting and/or electrically insulating) coating. The flexible substrate 830 containing the absorptive material 820 can then be formed about the circuit edge 795. In addition to including the flexible substrate 830 and the absorptive layer 820, the flexible absorptive shield 810 can also include an adhesive layer 840. As previously discussed in relation to FIGS. 4, 5A, and 5B, the adhesive layer 840 can include a pressure sensitive adhesive, or a permanent adhesive, used for securing the flexible absorptive shield 810 to the circuit edge 795. The tape embodiment may be further prepared as a roll (i.e., a roll of tape), from which desired lengths of flexible absorptive shield are removed and applied to the circuit edge 795. In a similar tape roll embodiment, the flexible dielectric substrate is replaced with a flexible conducting substrate, the combined result providing shielding over a broader frequency range than either the absorptive material 820 or the conductive substrate 830 could individually provide (e.g., from below 1 GHz to above 1 GHz).

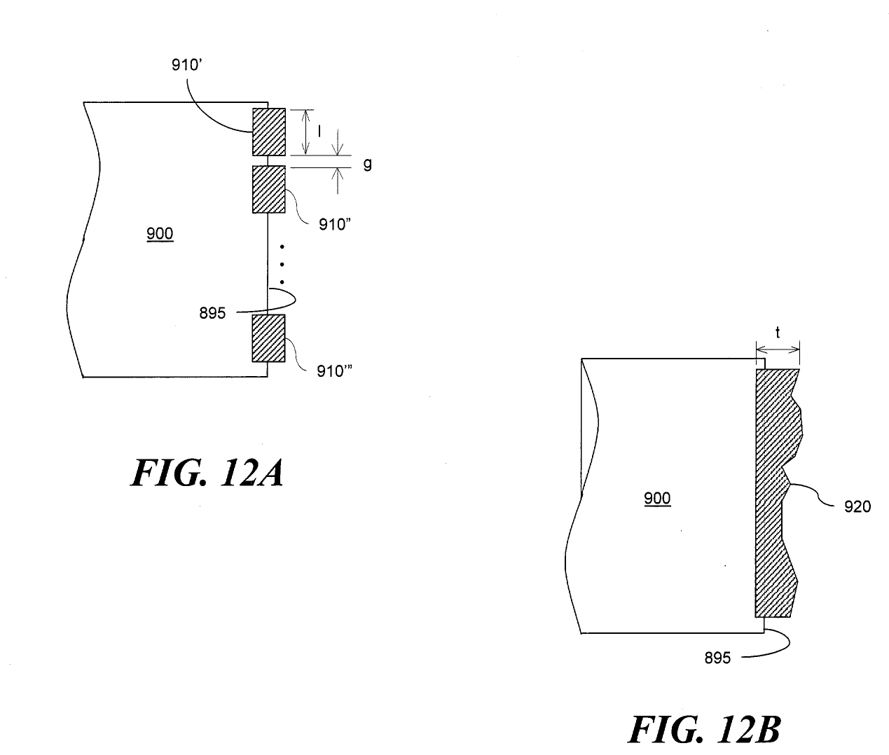

FIG. 12A is a schematic diagram depicting an embodiment in which more than one of any of the above-described absorptive shields are applied to an edge 895 of an exemplary electronic circuit 900. Thus, a group of absorptive components 910′, 910″, . . . , 910′″, generally 910, are applied to at least one circuit edge 895. Each absorptive component 910 is provided with a respective length, “1,” measured along the circuit edge 895. The lengths of each absorptive component 910 may be different from the other absorptive components 910. Further, each of the absorptive components 910 is positioned along the circuit edge 895, having a gap, g, to each neighboring absorptive component. The dimensions of the individual gaps between neighboring components are selectable, and may vary among adjacent absorptive components 910 residing along the same circuit edge 895.

In some embodiments, absorptive components 910 having different absorptive characteristics (e.g., formulated from different absorptive material) are collocated along the same circuit edge 895. Thus, the absorptive profile of the group of absorptive components 910 can be tailored along the circuit edge 895, concentrating different absorptive materials at different regions of the circuit edge 895, for example, concentrating absorptive components 910 having greater absorptive characteristics where needed. Such tailoring could be used as a cost savings measure, or to conserve weight and or space, and for achieving an overall improved absorptive performance.

FIG. 12B illustrates any of the above described absorptive shields in which the thickness, t, of the absorptive material is non-uniform along the circuit edge 895 as measured with respect to the circuit edge 895. Generally, the minimum thickness, t, should be greater than the previously-described, predetermined minimum thickness, tₘᵢₙ.

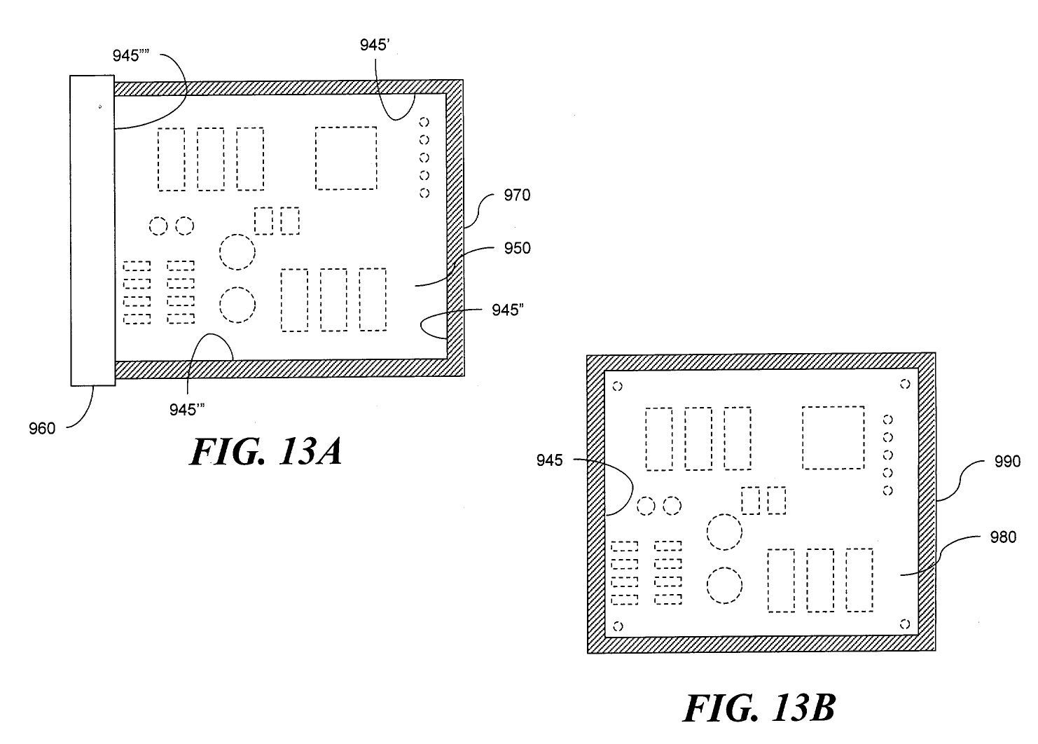

FIGS. 13A and 13B illustrate alternative exemplary embodiments in which the previously described absorptive shields are applied to multiple edges 945′, 945″, 945′″, 945″″, generally 945, of a generalized electronic circuit. FIG. 13A illustrates an electronic circuit 950 including an edge connector 960 along one circuit edge 945. An absorptive shield 970 is applied to the remaining three circuit edges 945 of the electronic circuit. FIG. 13B illustrates an electronic circuit 980 including an absorptive shield 990 along all circuit edges 945, or equivalently, along the entire perimeter of the electronic circuit 980. The electronic circuit 980 may be an electronic circuit board mounted on standoffs above a chassis, such that the absorptive material 990 can extend around the perimeter.

Having shown exemplary and preferred embodiments, one skilled in the art will realize that many variations are possible within the scope and spirit of the claimed invention. It is therefor the intention to limit the invention only by the scope of the claims, including all variants and equivalents.

What is claimed is:

1. A shield for reducing radio frequency (RF) interference associated with an electronic circuit, the shield comprising an RF absorber configured to be in electrical communication with an edge of the electronic circuit, wherein the RF absorber intercepts electromagnetic fields, removing a portion of the energy contained therein through energy conversion, thereby reducing associated RF interference.

2. The shield of claim 1, further comprising a fastener attached to the RF absorber for maintaining the RF absorber in a substantially fixed relationship to the electronic circuit when in electrical communication therewith.

3. The shield of claim 2, wherein the fastener comprises an adhesive.

4. The shield of claim 2, wherein the fastener comprises a mechanical fastener.

5. The shield of claim 2, wherein the fastener is electrically conductive.

6. The shield of claim 2, wherein the fastener comprises a clip.

7. The shield of claim 2, wherein the fastener comprises an inside surface and an outside surface, wherein the RF absorber is deposited upon the outside surface and the inside surface is attached to the electronic circuit.

8. The shield of claim 1, further comprising a substrate upon which the RF absorber is deposited in a layer.

9. The shield of claim 8, wherein the substrate is flexible.

10. The shield of claim 8, wherein the combined substrate and RF absorber is a tape form.

11. The shield of claim 8, wherein the substrate is substantially non-electrically-conducting.

12. The shield of claim 10, further comprising an adhesive layer.

13. The shield of claim 1, wherein the RF absorber exhibits a relative magnetic permeability greater than about 1 in a frequency range from about 1 GHz up to at least about 100 GHz.

14. The shield of claim 1, wherein the RF absorber comprises a material selected from the group of consisting of alumina, sapphire, silica, epoxy, titanium dioxide, steel wool, carbon-impregnated rubber, ferrite, iron, iron silicide, graphite, carbon in a plastic stranded carrier, paste composites, and combinations thereof.

15. The shield of claim 1, wherein the RF absorber is a composition comprising RF absorbing particles bound and a supporting matrix.

16. The shield of claim 15, wherein the matrix comprises a polymer selected from the group of consisting of silicone, fluorosilicone, isoprene, nitrile, polyethylene, chlorosulfonated polyethylene, neoprene, fluoroelastomer, urethane, thermoplastic, thermoplastic elastomer (TPE), polyamide TPE, thermoplastic polyurethane (TPU), and combinations thereof.

17. The shield of claim 15, wherein the matrix comprises an epoxy.

18. The shield of claim 1 comprising a shielding effectiveness of at least about 3 dB in a frequency range from about 1 GHz up to at least about 100 GHz.

19. The shield of claim 1, wherein the RF absorber has a skin depth, δ, and a thickness with respect to the edge of the electronic circuit, wherein the thickness is greater than about one skin depth (i.e., 1δ) in a frequency range extending above about 1 GHz.

20. The shield of claim 1, wherein the RF absorber is configured to have a non-uniform thickness with respect to the edge of the electronic circuit when in electrical communication therewith.

21. The shield of claim 1, wherein the RF absorber comprises a plurality of RF absorbing components spaced from each other when in electrical communication with the electronic circuit.

22. The shield of claim 1, wherein when the RF absorber is in electrical communication with the edge of the electronic circuit, a physical gap is maintained relative thereto along at least a portion of the edge.

23. The shield of claim 1, wherein the RF absorber comprises a first layer comprising a first RF absorbing material and a second layer comprising a second RF absorbing material.

24. The shield of claim 1, wherein the electronic circuit comprises a printed circuit board.

25. The shield of claim 1, wherein the RF absorber intercepts electromagnetic fields, removing a portion of the energy contained therein through heat conversion.

26. A method for reducing radio frequency (RF) interference associated with an electronic circuit comprising the steps of:
(a) providing an RF absorber; and
(b) positioning the RF absorber to be in electrical communication with a first edge of an electronic circuit, wherein the positioned absorber intercepts electromagnetic fields, removing a portion of the energy contained therein through energy conversion, thereby reducing the associated RF interference.

27. The method of claim 26, further comprising the step of fastening the RF absorber to the first edge of the electronic circuit.

28. The method of claim 27, wherein the fastening step comprises using a mechanical fastener.

29. The method of claim 27, wherein the fastening step comprises using an adhesive.

30. The method of claim 26, wherein the RF absorber is deposited on the first edge of the electronic circuit.

31. The method of claim 26, wherein the RF absorber comprises a plurality of RF absorbing components, wherein each is selectively deposited on the first edge of the electronic circuit and spaced from an adjacent RF absorbing component.

32. The method of claim 26, wherein the RF absorber is deposited on the first edge of the electronic circuit, such that a thickness of the deposited RF absorber along the first edge is non-uniform with respect to the first edge.

33. The method of claim 26, wherein the RF absorber comprises a first layer comprising a first absorbing material and a second layer comprising a second absorbing material.

34. The method of claim 30, wherein the RF absorber is painted onto the first edge of the electronic circuit.

35. The method of claim 30, wherein the RF absorber is sputtered onto the first edge of the electronic circuit.

36. The method of claim 30, wherein the RF absorber is deposited onto the first edge of the electronic circuit using chemical vapor deposition.

37. The method of claim 26, wherein the step of positioning the RF absorber comprises maintaining a physical gap relative to the first edge of the electrical circuit along at least a portion thereof.

38. The method of claim 26, further comprising the step of positioning the RF absorber to be in electrical communication with a second edge of the electronic circuit.

39. A shield for reducing radio frequency (RF) interference associated with an electronic circuit, the shield comprising:
an RF absorber; and
a fastener attached to the RF absorber, wherein the shield is attached to a first edge of the electronic circuit, the shield intercepting electromagnetic fields and removing a portion of the energy contained therein through energy conversion, thereby reducing the associated RF interference.

40. The shield of claim 39, wherein the electronic circuit comprises a printed circuit board.

41. The shield of claim 39, wherein the electronic circuit comprises a multi-layer printed circuit board.

42. The shield of claim 39, wherein the shield is removably attached to a first edge of the electronic circuit.

43. A shield for reducing radio frequency (RF) interference associated with an electronic circuit, the shield comprising means for absorbing RF energy, configured to be in electrical communication with an edge of the electronic circuit, wherein the means for absorbing RF energy intercepts electromagnetic fields, removing a portion of the energy contained therein through conversion, thereby reducing associated RF interference.

44. The shield of claim 43 further comprising means for securing the RF absorbing means to the electronic circuit.
